(19) United States
(12) Patent Application Publication
(10) Pub. No.: US 2024/0128716 A1
(43) Pub. Date: Apr. 18, 2024

(54) Semiconductor Optical Integrated Device

(71) Applicant: Nippon Telegraph and Telephone Corporation, Tokyo (JP)

(72) Inventors: Yasuhiko Nakanishi, Musashino-shi, Tokyo (JP); Takahiko Shindo, Musashino-shi, Tokyo (JP); Shigeru Kanazawa, Musashino-shi, Tokyo (JP); Meishin Chin, Musashino-shi, Tokyo (JP); Yasuaki Hashizume, Musashino-shi, Tokyo (JP)

(21) Appl. No.: 18/264,913

(22) PCT Filed: Mar. 23, 2021
(86) PCT No.: PCT/JP2021/012077

§ 371 Date: Aug. 9, 2023

(51) Int. Cl. H01S 5/0683; H01S 5/026; H01S 5/068; H01S 5/125

(52) U.S. Cl. CPC H01S 5/0683; H01S 5/0265; H01S 5/06821; H01S 5/125; H01S 5/02212

(57) ABSTRACT

To detect deterioration of an SOA and perform feedback control to keep light intensity of output light constant in a configuration in which a DFB laser, an EA modulator, and the SOA are monolithically integrated. A semiconductor optical integrated element includes: a DFB laser that outputs continuous light; an EA modulator that modulates the continuous light; a first multimode interference coupler that inputs the modulated light from a first input port, divides the modulated light, and outputs the divided modulated light from two or more output ports; semiconductor optical amplifiers that are connected to respective output ports of the first multimode interference coupler and amplify each of the divided modulated light; a second multimode interference coupler that has input ports connected to respective outputs of the semiconductor optical amplifiers, multiplexes the amplified modulated light, and outputs the multiplexed modulated light from a first output port; and a monitoring waveguide.

### TECHNICAL FIELD

The present invention relates to a distributed feedback semiconductor optical integrated element, and particularly relates to a semiconductor optical integrated element that monitors light intensity.

### BACKGROUND ART

Distributed feedback (DFB) lasers are excellent in single wavelength. As an application form thereof, a semiconductor optical integrated element (EA-DFB laser) monolithically integrated with an electro-absorption (EA) modulator on a single substrate is known. The EA-DFB laser is widely used in high-speed optical communication systems because of high extinction characteristics and broadband characteristics of the EA modulator.

In the EA-DFB laser, it is desirable to keep the light intensity of an output optical signal constant for stable operation of the system. Therefore, the light intensity is monitored and feedback control (APC: Auto Power Control) of current injected into a DFB laser has been performed so that the monitored light intensity becomes constant (see, for example, Patent Literature 1). Conventionally, as a configuration for monitoring light intensity of a DFB laser in an optical transmitter including a DFB laser and an EA modulator, a configuration including a light receiver behind the DFB laser is disclosed (see, for example, Patent Literature 1).

Furthermore, as an application form of the EA-DFB laser, a semiconductor optical integrated element (AXEL: soa Assisted eXtended reach Ea-dfb Laser) that realizes long-distance transmission by monolithically integrating a semiconductor optical amplifier (SOA) on the same substrate in addition to the DFB laser and the EA modulator is known (see, for example, Patent Literature 2).

In the optical transmitter in which the AXEL is mounted, only the light intensity of the DFB laser can be monitored when the light intensity is monitored at the position of the light receiver based on the conventional configuration, that is, at the subsequent stage of the DFB laser. Therefore, when the gain of the SOA decreases due to the deterioration of the SOA, the monitoring cannot detect the phenomenon, and thus the light intensity of the output light of the optical transmitter cannot be made constant by the feedback control.

Thus, by monitoring the light intensity at the preceding stage of the SOA, it is possible to detect a decrease in the amplification factor of the SOA accompanying the deterioration of the SOA. However, in a case where the monitoring is performed in the preceding stage of the SOA, it is necessary to tap the output light from the SOA, and therefore, there are disadvantages such as an increase in cost due to an increase in the number of members due to the tapping and a decrease in light intensity of the output light of the optical transmitter.

### CITATION LIST

### Patent Literature

Patent Literature 1: JP 5631773 B2

Patent Literature 2: JP 5823920 B2

### SUMMARY OF INVENTION

An object of the present invention is to provide a semiconductor optical integrated element capable of detecting deterioration of an SOA and performing feedback control to keep light intensity of output light constant in a configuration in which a DFB laser, an EA modulator, and the SOA are monolithically integrated.

In order to achieve such an object, a semiconductor optical integrated element of an embodiment of the present invention includes: a DFB laser that outputs continuous light; an EA modulator that modulates the continuous light and outputs modulated light; a first multimode interference coupler that inputs the modulated light from a first input port, divides the modulated light, and outputs the divided modulated light from two or more output ports; semiconductor optical amplifiers that are connected to respective output ports of the first multimode interference coupler and amplify each of the divided modulated light; a second multimode interference coupler that has input ports connected to respective outputs of the semiconductor optical amplifiers, multiplexes the amplified modulated light, and outputs the multiplexed modulated light from a first output port; and a monitoring waveguide that is connected to a second input port of the first multimode interference coupler.

### BRIEF DESCRIPTION OF DRAWINGS

FIG. 1 is a top diagram illustrating a configuration example of a semiconductor optical integrated element according to a first embodiment of the present invention.

FIG. 2 is a diagram illustrating a configuration example of an optical transmitter in which an optical semiconductor integrated element is mounted.

FIG. 3 is a top diagram illustrating a modification of the semiconductor optical integrated element of the first embodiment.

FIG. 4 is a top diagram illustrating a configuration example of a semiconductor optical integrated element according to a second embodiment of the present invention.

FIG. 5 is a top diagram illustrating a modification of the semiconductor optical integrated element of the second embodiment.

FIG. 6 is a top diagram illustrating a configuration example of a semiconductor optical integrated element according to a third embodiment of the present invention.

FIG. 7 is a diagram illustrating another configuration example of an optical transmitter in which an optical semiconductor integrated element is mounted.

FIG. 8 is a top diagram illustrating a first modification of the semiconductor optical integrated element of the third embodiment.

FIG. 9 is a top diagram illustrating a second modification of the semiconductor optical integrated element of the third embodiment.

### DESCRIPTION OF EMBODIMENTS

The following is a detailed description of embodiments of the present invention with reference to the drawings.

### First Embodiment

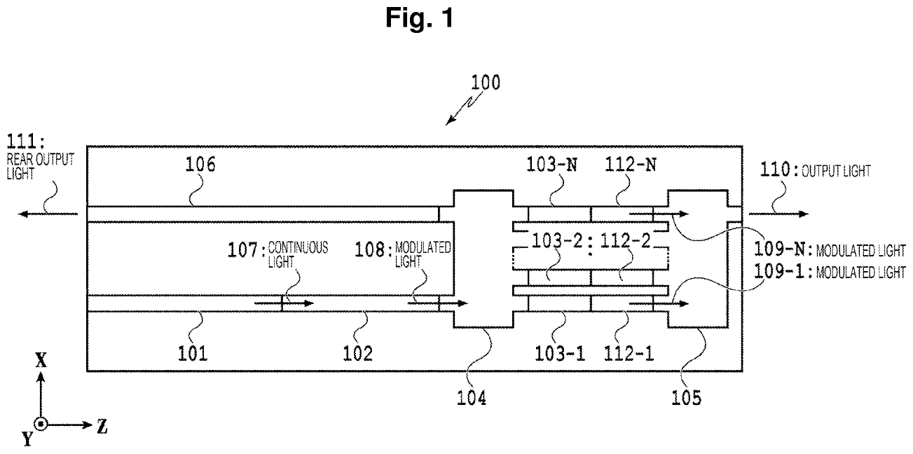

FIG. 1 illustrates a configuration example of a semiconductor optical integrated element 100 according to the first embodiment of the present invention. The semiconductor optical integrated element 100 includes a DFB laser 101, an EA modulator 102 connected to the DFB laser, a 2×N multimode interference coupler (MMI) 104 with input 2-port output N-ports connected to an output end of the EA modulator 102, N SOAs 103-1 to 103-N connected to respective output ports of the 2×N-MMI 104, waveguides 112-1 to 112-N connected to output ports of respective SOAs 103, an N×1-MMI 105 with input N-port output 1-port connected to the waveguides 112, and a monitoring waveguide 106 connected to the input port of the 2×N-MMI 104, which are integrated on a single substrate.

Continuous light 107 output from the DFB laser 101 is input to the EA modulator 102, modulated by the EA modulator 102, and output as modulated light 108. The modulated light 108 is input to one input port of the 2×N-MMI 104, divided into N, and input to the SOAs 103 connected to the respective output ports of the 2×N-MMI 104. In the SOAs 103, the N-divided modulated light 108 is amplified and input to the respective input ports of the N×1-MMI 105 via the waveguides 112. In the N×1-MMI 105, each amplified modulated light 109 is multiplexed, output from the output port of the N×1-MMI, and become output light 110.

In the SOAs 103, light called amplified spontaneous emission (ASE light) associated with optical amplification is emitted. The ASE light is output not only in a direction of the N×1-MMI 105 on the output side of the SOAs 103 but also in a direction of the 2×N-MMI 104 on the input side. The ASE light is output to the monitoring waveguide 106 connected to the other input port of the 2×N-MMI 104, and is output as rear output light 111. It is known that a change in light intensity of the output ASE light is proportional to a change in gain of the SOAs 103.

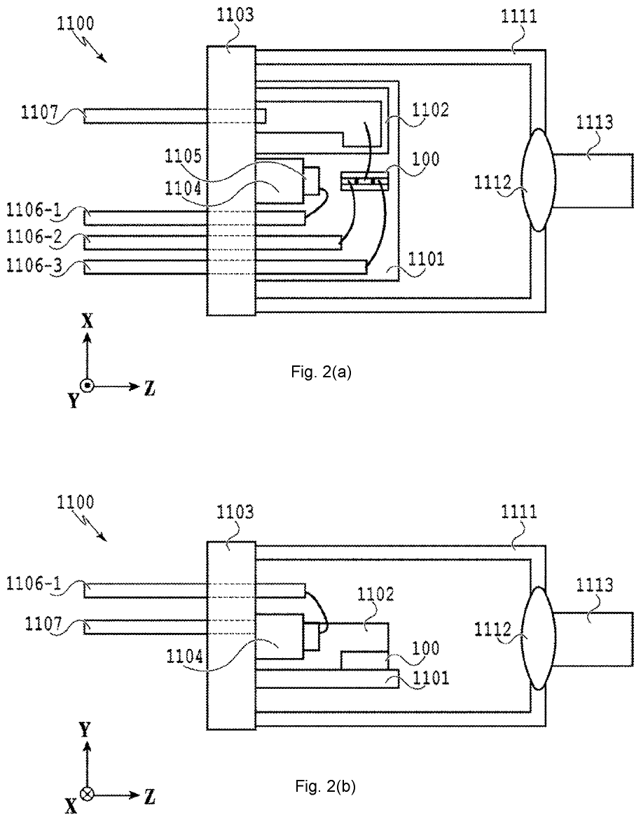

FIG. 2 illustrates a configuration example of an optical transmitter 1100 in which the optical semiconductor integrated element 100 is mounted. FIG. 2(a) is a top diagram, and FIG. 2(b) is a side diagram. FIG. 2(a) illustrates a configuration example of the optical transmitter 1100 when the optical semiconductor integrated element 100 mounted on a carrier 1101 is viewed from the same viewpoint as FIG. 1. The carrier 1101, a high frequency wiring substrate 1102, and a monitor PD carrier 1104 are mounted on a stem 1103. The optical semiconductor integrated element 100 is mounted on the carrier 1101, and a monitor PD 1105 is mounted on the monitor PD carrier 1104. The stem 1103 is provided with DC pins 1106-1 to 1106-3 and a coaxial pin 1107 in the form of penetrating the stem 1103.

Current or voltage to the DFB laser 101, the SOAs 103, and the monitor PD 1105 of the optical semiconductor integrated element 100 is supplied via the DC pins 1106. A high frequency signal to the EA modulator 102 of the optical semiconductor integrated element 100 is supplied via the coaxial pin 1107 and the high frequency wiring substrate 1102. A cap 1111 with a lens 1112 is welded to the stem 1103 on which the optical semiconductor integrated element 100 and the like are mounted, and the optical semiconductor integrated element 100 and the like are sealed. The output light 110 from the optical semiconductor integrated element 100 is optically coupled to an optical fiber connected to a receptacle 1113 via the lens 1112.

The output light 110 of the optical transmitter 1100 is emitted from the end face of the optical semiconductor integrated element 100 in the Z-axis direction. The rear output light 111 from the optical semiconductor integrated element 100 is input to the monitor PD 1105. A current corresponding to the light intensity of the rear output light 111 input to the monitor PD 1105 is output to the DC pin 1106-1. As described above, since the light intensity of the ASE light, which is the rear output light 111, changes according to a change in gain of the SOAs 103, feedback control is performed with respect to the value of the current detected by the monitor PD 1105 according to the light intensity. That is, by changing the current applied to the SOAs 103, the light intensity of the output light 110 of the optical transmitter 1100 can be kept constant.

Note that the number of output ports of the 2×N-MMI 104 and the number of input ports of the N×1-MMI 105, that is, the number of divisions of the modulated light 108 is N, but it is sufficient if N is two or more. When the number of the SOAs 103 is large, the gain of one SOA may be small in order to obtain the light intensity required as the output light 110 of the optical transmitter 1100, and it is possible to contribute to improvement of the reliability of the SOAs.

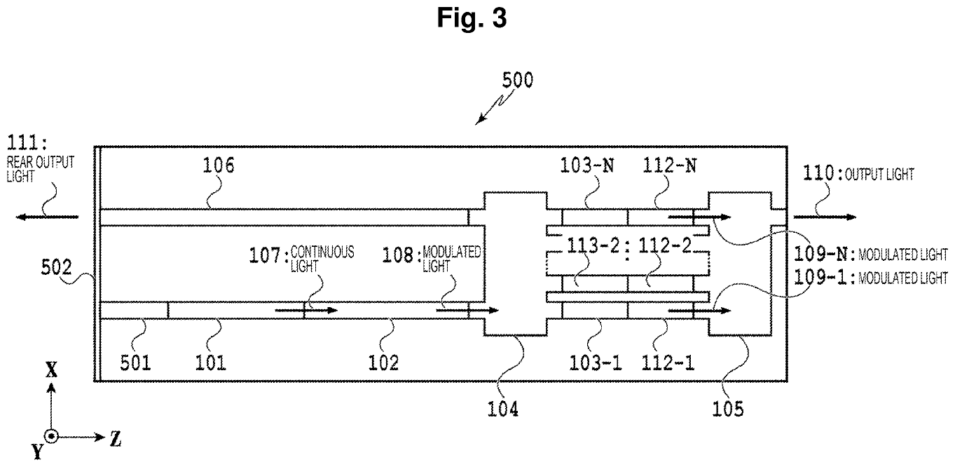

FIG. 3 illustrates a modification of the semiconductor optical integrated element of the first embodiment. A difference from the semiconductor optical integrated element 100 is that an anti-reflective (AR) coat 502 is mounted on an output end face of the monitoring waveguide 106 of an optical semiconductor integrated element 500 in order to efficiently output the rear output light 111. Furthermore, in order to increase the output of the DFB laser 101, a distributed Bragg reflector (DBR) 501 may be formed on the opposite side (minus Z direction) to the side where the continuous light of the DFB laser is output.

### Second Embodiment

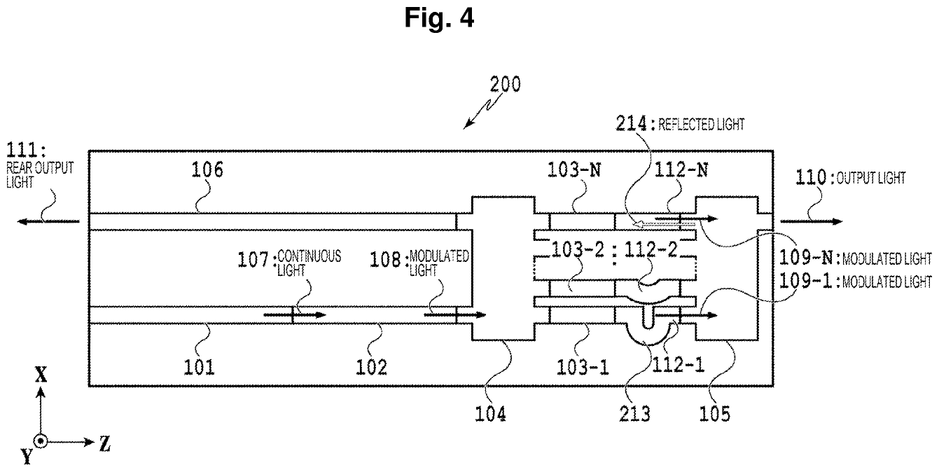

FIG. 4 illustrates a configuration example of a semiconductor optical integrated element 200 according to the second embodiment of the present invention. The semiconductor optical integrated element 200 includes a DFB laser 101, an EA modulator 102 connected to the DFB laser, a 2×N multimode interference coupler (MMI) 104 with input 2-ports output N-ports connected to an output end of the EA modulator 102, N SOAs 103-1 to 103-N connected to respective output ports of the 2×N-MMI 104, waveguides 112-1 to 112-N including a phase adjustment unit 213 connected to output ports of respective SOAs 103, an N×1-MMI 105 with input N-ports output 1-port connected to the waveguides 112, and a monitoring waveguide 106 connected to the input port of the 2×N-MMI 104, which are integrated on a single substrate.

Continuous light 107 output from the DFB laser 101 is input to the EA modulator 102, modulated by the EA modulator 102, and output as modulated light 108. The modulated light 108 is input to one input port of the 2×N-MMI 104, divided into N, and input to the SOAs 103 connected to the respective output ports of the 2×N-MMI 104. In the SOAs 103, the N-divided modulated light 108 is amplified and input to the respective input ports of the N×1-MMI 105 via the waveguides 112 including the phase adjustment unit 213.

In the phase adjustment unit 213, a propagation delay according to the waveguide length of the phase adjustment unit 213 is applied to the modulated light 108. In the N×1-MMI 105, each amplified modulated light 109 is multiplexed and is divided into a component that is output from the output port of the N×1-MMI and becomes the output light 110 and reflected light 214 that is reflected at the boundary of the N×1-MMI 105 in the +Z direction and returns to the waveguides 112. A part of the reflected light 214 is output to the monitoring waveguide 106 via the SOAs 103 and the 2×N-MMI 104.

In the SOAs 103, the ASE light associated with optical amplification is emitted not only in a direction of the N×1-MMI 105 on the output side of the SOAs 103 but also in a direction of the 2×N-MMI 104 on the input side. The ASE light is input to the waveguide 106 connected to the other input port of the 2×N-MMI 104. The ASE light and the component of a part of the reflected light 214 are transmitted through the monitoring waveguide 106 and output as the rear output light 111.

In the optical transmitter 1100 illustrated in FIG. 2, by mounting the optical semiconductor element 200 instead of the optical semiconductor element 100, it is possible to achieve a similar operation and effect. The rear output light 111 from the optical semiconductor integrated element 200 is input to the monitor PD 1105. A current corresponding to the light intensity of the rear output light 111 input to the monitor PD 1105 is output to the DC pin 1106-1. As described above, the light intensity of the ASE light, which is a component of the rear output light 111, changes according to a change in gain of the SOAs 103, and the light intensity of the reflected light changes according to a change in output of the DFB laser 101. The value of the current detected by the monitor PD 1105 is subjected to feedback control according to the light intensity. That is, by changing the current applied to the SOAs 103 or the current applied to the DFB laser 101, the light intensity of the output light 110 of the optical transmitter 1100 can be kept constant.

Note that the number of output ports of the 2×N-MMI 104 and the number of input ports of the N×1-MMI 105, that is, the number of divisions of the modulated light 108 is N, but it is sufficient if N is two or more.

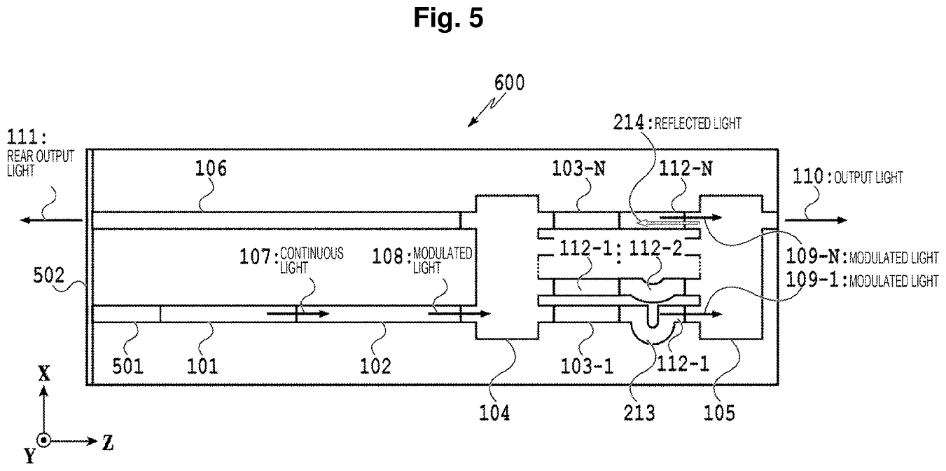

FIG. 5 illustrates a modification of the semiconductor optical integrated element of the second embodiment. A difference from the semiconductor optical integrated element 200 is that an AR coat 502 is mounted on an output end face of the monitoring waveguide 106 of an optical semiconductor integrated element 600 in order to efficiently output the rear output light 111. Furthermore, in order to increase the output of the DFB laser 101, a DBR 501 may be formed on the opposite side (minus Z direction) to the side where the continuous light of the DFB laser is output.

### Third Embodiment

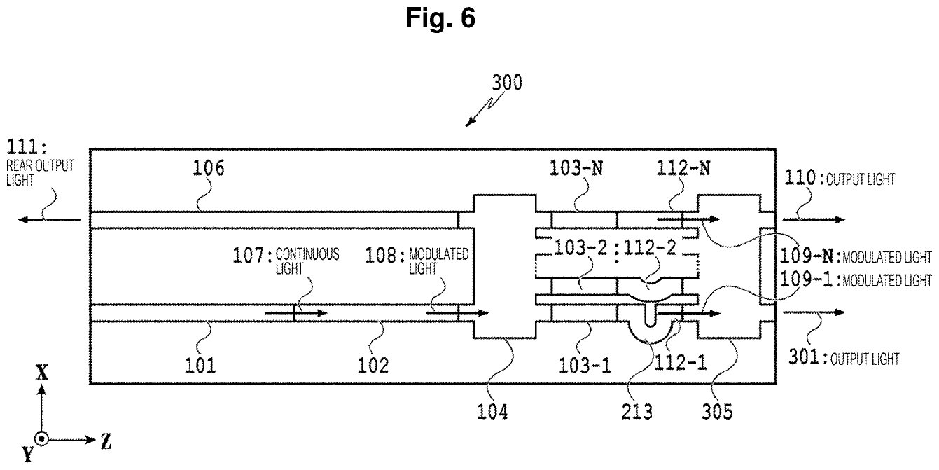

FIG. 6 illustrates a configuration example of a semiconductor optical integrated element 300 according to the third embodiment of the present invention. The semiconductor optical integrated element 300 includes a DFB laser 101, an EA modulator 102 connected to the DFB laser, a 2×N multimode interference coupler (MMI) 104 with input 2-ports output N-ports connected to an output end of the EA modulator 102, N SOAs 103-1 to 103-N connected to respective output ports of the 2×N-MMI 104, waveguides 112-1 to 112-N including a phase adjustment unit 213 connected to output ports of respective SOAs 103, an N×2-MMI 305 with input N-ports output 2-ports connected to the waveguides 112, and a monitoring waveguide 106 connected to the input port of the 2×N-MMI 104, which are integrated on a single substrate.

Continuous light 107 output from the DFB laser 101 is input to the EA modulator 102, modulated by the EA modulator 102, and output as modulated light 108. The modulated light 108 is input to one input port of the 2×N-MMI 104, divided into N, and input to the SOAs 103 connected to the respective output ports of the 2×N-MMI 104. In the SOAs 103, the N-divided modulated light 108 is amplified and input to the respective input ports of the N×2-MMI 305 via the waveguides 112 including the phase adjustment unit 213.

In the phase adjustment unit 213, a delay according to the waveguide length of the phase adjustment unit 213 is applied to the modulated light 108. In the N×2-MMI 305, each amplified modulated light 109 is multiplexed and is divided into a component that is output from one output port of the N×2-MMI 305 and becomes the output light 110 and a component that is output from the other output port and becomes output light 301.

In the SOAs 103, the ASE light associated with optical amplification is emitted not only in a direction of the N×2-MMI 305 on the output side of the SOAs 103 but also in a direction of the 2×N-MMI 104 on the input side. The ASE light is input to the monitoring waveguide 106 connected to the other input port of the 2×N-MMI 104, and is output as rear output light 111.

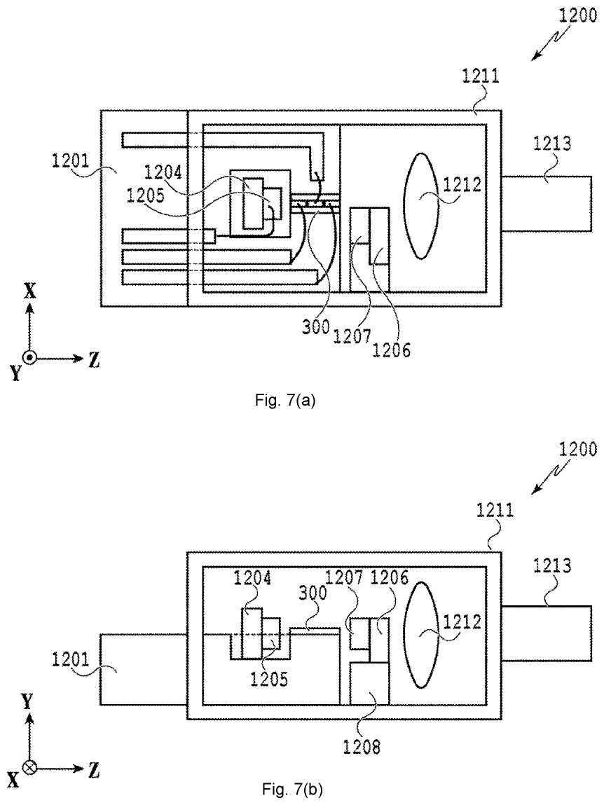

FIG. 7 illustrates another configuration example of an optical transmitter 1200 in which the optical semiconductor integrated element 300 is mounted. FIG. 7(a) is a top diagram, and FIG. 7(b) is a side diagram. FIG. 7(a) illustrates a configuration example of the optical transmitter 1200 when the optical semiconductor integrated element 300 mounted on a wiring substrate 1201 is viewed from the same viewpoint as FIG. 6. A monitor PD carrier 1204 on which a monitor PD 1205 that receives the rear output light 111 is mounted is fixed on the wiring substrate 1201. Current or voltage to the DFB laser 101, the SOAs 103, and the monitor PD 1205 of the optical semiconductor integrated element 300 is supplied via the wiring substrate 1201. A high frequency signal to the EA modulator 102 of the optical semiconductor integrated element 300 is also supplied via the wiring substrate 1201.

The wiring substrate 1201 on which the optical semiconductor integrated element 300 and the like are mounted is accommodated in a package 1211. The output light 110 from the optical semiconductor integrated element 300 is optically coupled to an optical fiber connected to a receptacle 1213 via a lens 1212. In addition, a monitor PD carrier 12066 on which a monitor PD 1207 that receives the output light 301 is mounted is fixed to the package 1211.

As described above, since the light intensity of the ASE light, which is the rear output light 111, changes according to a change in gain of the SOAs 103, feedback control is performed with respect to the value of the current detected by the monitor PD 1205 according to the light intensity. That is, by changing the current applied to the SOAs 103, the light intensity of the output light 110 of the optical transmitter 1200 can be kept constant.

In addition, in the feedback control, the output light 301 can also be used for monitoring. For example, the output light 110 and the output light 301 are divided at a division ratio of 9:1, and the output light 301 is monitored by the monitor PD 1207 to perform feedback control. That is, by changing the current applied to the DFB laser 101, the light intensity of the output light 110 of the optical transmitter 1200 can be kept constant. Unlike the second embodiment, feedback control can be individually performed on the DFB laser 101 and the SOAs 103. In addition, according to the third embodiment, since a circuit for tapping the output light 110 is not required for feedback control of the DFB laser 101, a low-cost optical module can be realized.

Note that the number of output ports of the 2×N-MMI 104 and the number of input ports of the N×2-MMI 305, that is, the number of divisions of the modulated light 108 is N, but it is sufficient if N is two or more.

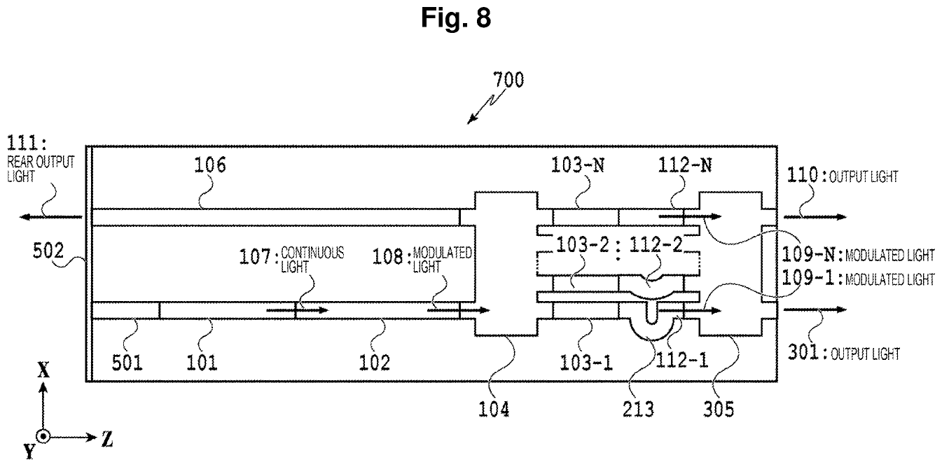

FIG. 8 illustrates a first modification of the semiconductor optical integrated element of the third embodiment. A difference from the semiconductor optical integrated element 300 is that an AR coat 502 is mounted on an output end face of the monitoring waveguide 106 of an optical semiconductor integrated element 700 in order to efficiently output the rear output light 111. Furthermore, in order to increase the output of the DFB laser 101, a DBR 501 may be formed on the opposite side (minus Z direction) to the side where the continuous light of the DFB laser is output.

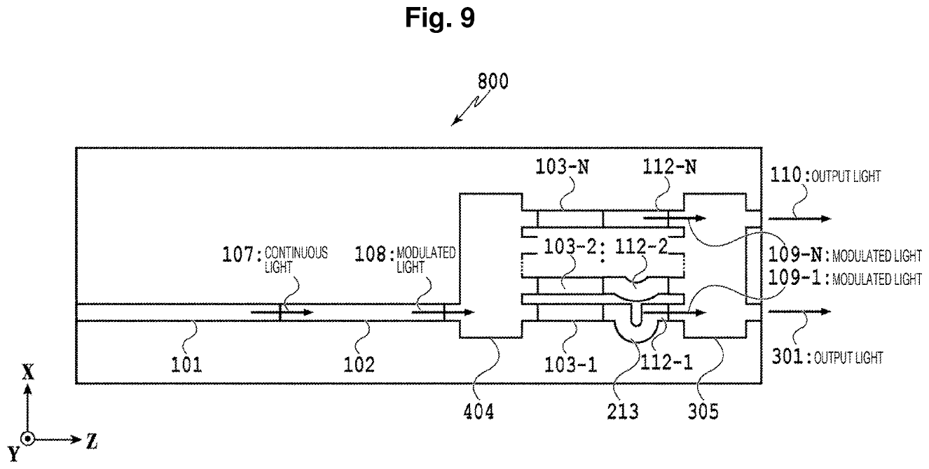

FIG. 9 illustrates a second modification of the semiconductor optical integrated element of the third embodiment. A difference from the semiconductor optical integrated element 300 is that a 1×N-MMI 404 is used instead of the 2×N-MMI 104. In an optical semiconductor integrated element 800, monitoring using the rear output light 111 is omitted, and the monitoring waveguide 106 is not provided in order to perform monitoring by using the output light 110 or the output light 301. Note that the number of output ports of the 1×N-MMI 404 and the number of input ports of the N×2-MMI 305, that is, the number of divisions of the modulated light 108 is N, but it is sufficient if N is two or more.

1. A semiconductor optical integrated element comprising:
a DFB laser that outputs continuous light;
an EA modulator that modulates the continuous light and outputs modulated light;
a first multimode interference coupler that inputs the modulated light from a first input port, divides the modulated light, and outputs the divided modulated light from two or more output ports;
semiconductor optical amplifiers that are connected to respective output ports of the first multimode interference coupler and amplify each of the divided modulated light;
a second multimode interference coupler that has input ports connected to respective outputs of the semiconductor optical amplifiers, multiplexes the amplified modulated light, and outputs the multiplexed modulated light from a first output port; and
a monitoring waveguide that is connected to a second input port of the first multimode interference coupler.

2. The semiconductor optical integrated element according to claim 1, comprising:
a phase adjustment unit that applies a propagation delay in waveguides connecting respective outputs of the semiconductor optical amplifiers and input ports of the second multimode interference coupler.

3. The semiconductor optical integrated element according to claim 1, wherein the second multimode interference coupler further includes a second output port, multiplexes the amplified modulated light, and divides and outputs the modulated light to the first and second output ports.

4. The semiconductor optical integrated element according to claim 1, wherein an AR coat is mounted on an output end face of the monitoring waveguide.

5. A semiconductor optical integrated element comprising:
a DFB laser that outputs continuous light;
an EA modulator that modulates the continuous light and outputs modulated light;
a first multimode interference coupler that inputs the modulated light from an input port, divides the modulated light, and outputs the divided modulated light from two or more output ports;
semiconductor optical amplifiers that are connected to respective output ports of the first multimode interference coupler and amplify each of the divided modulated light; and
a second multimode interference coupler that has input ports connected to respective outputs of the semiconductor optical amplifiers, multiplexes the amplified modulated light, and divides and outputs the multiplexed modulated light to two output ports.

6. The semiconductor optical integrated element according to claim 1, wherein a DBR is connected to a side of the DFB laser opposite to a side where the continuous light is output.

7. The semiconductor optical integrated element according to claim 2, wherein the second multimode interference coupler further includes a second output port, multiplexes the amplified modulated light, and divides and outputs the modulated light to the first and second output ports.

8. The semiconductor optical integrated element according to claim 2, wherein an AR coat is mounted on an output end face of the monitoring waveguide.

9. The semiconductor optical integrated element according to claim 3, wherein an AR coat is mounted on an output end face of the monitoring waveguide.

10. The semiconductor optical integrated element according to claim 2, wherein a DBR is connected to a side of the DFB laser opposite to a side where the continuous light is output.

11. The semiconductor optical integrated element according to claim 3, wherein a DBR is connected to a side of the DFB laser opposite to a side where the continuous light is output.

12. The semiconductor optical integrated element according to claim 4, wherein a DBR is connected to a side of the DFB laser opposite to a side where the continuous light is output.

13. The semiconductor optical integrated element according to claim 5, wherein a DBR is connected to a side of the DFB laser opposite to a side where the continuous light is output.
